(19) United States
(12) Patent Application Publication
(10) Pub. No.: US 2013/0176260 A1
(43) Pub. Date: Jul. 11, 2013

(54) TOUCH PANEL MOTHER SUBSTRATE AND TOUCH PANEL CUT THEREFROM

(71) Applicants: Hijiri Nakahara, Osaka-shi (JP); Yasuhiro Kohara, Osaka-shi (JP)

(72) Inventors: Hijiri Nakahara, Osaka-shi (JP); Yasuhiro Kohara, Osaka-shi (JP)

(73) Assignee: SHARP KABUSHIKI KAISHA, Osaka-shi, Osaka (JP)

(21) Appl. No.: 13/823,764

(22) PCT Filed: Sep. 29, 2011
(86) PCT No.: PCT/JP2011/072373

§ 371 Date: Mar. 15, 2013

(30) Foreign Application Priority Data
Oct. 8, 2010 (JP) 2010-228803

(51) Int. Cl. H05K 3/28

(52) U.S. Cl. CPC H05K 3/28
USPC 345/173; 427/96.2; 428/172

(57) ABSTRACT

An objective of the present invention is to provide a touch panel mother substrate that has a novel structure and facilities the cutting of a touch panel, and a touch panel that has been cut from the touch panel mother substrate. A plurality of touch panel units (50) that are to be touch panels (10) after being cut is formed on a touch panel mother substrate (48). The touch panel mother substrate (48) includes an organic resin film (46) that is deposited on the front side of the touch panel mother substrate (48), and a cutting groove (52) that opens at the surface of the organic resin film (46) and extends in a predetermined direction. The materials of a bottom surface (54) of the cutting groove (52) and a back surface (58) of the touch panel mother substrate (46) have the same main ingredient.

### TECHNICAL FIELD

The present invention relates to a touch panel mother substrate and a touch panel cut from the touch panel mother substrate.

### BACKGROUND ART

A touch panel has conventionally been known as an input device for detecting a position touched with a finger, a pen, or the like. For example, Japanese Patent Application Laid-Open No. 2008-233976 (Patent Document 1) discloses a capacitive type touch panel.

A protective film is formed on the touch panel in such a way as to cover a touch electrode used for detecting the touched position. An organic resin film including an acrylic resin is adopted as the protective film in terms of transmittance, hardness, or the like.

By the way, a touch panel is generally fabricated by cutting a plurality of touch panel units formed on a touch panel mother substrate. Thus, it is preferable to efficiently cut the touch panel units from the touch panel mother substrate.

However, Using an organic resin film as the protective film means that the front side of the touch panel mother substrate has a different material from the back side. As a result of that, for example, a condition for use of the tool for cutting the touch panels from the touch panel mother substrate needs to be changed depending on which side is cut, the front side or the back side of the touch panel mother substrate. Further, there is a problem, for example, that the touch panel is broken when being cut from the touch panel mother substrate.

### DISCLOSURE OF THE INVENTION

An objective of the present invention is to provide a touch panel mother substrate having a novel structure and capable of facilitating the cutting of the touch panels therefrom, and a touch panel cut from the touch panel mother substrate.

A touch panel mother substrate according to the present invention is a touch panel mother substrate on which a plurality of touch panel units is formed. Each of the units becomes a touch panel after being cut from the mother substrate. The mother substrate includes an organic resin film deposited on the front side of the touch panel mother substrate, and a cutting groove opened on the surface of the organic resin film and extending in a predetermined direction. The materials of the bottom surface of the cutting groove and the back surface of the touch panel mother substrate have the same main ingredient.

According to a touch panel mother substrate of the present invention, the cutting of touch panels can be facilitated.

### BRIEF DESCRIPTION OF THE DRAWINGS

FIG. 1 is a plan view for illustrating a touch panel as an embodiment of the present invention.

FIG. 2 is a cross-sectional view taken along line II-II of FIG. 1.

FIG. 3 is a cross-sectional view taken along line III-III of FIG. 1.

FIG. 4 is an enlarged cross-sectional view for illustrating the main parts in a IV-IV direction of FIG. 1.

FIG. 5 is a plan view for illustrating a touch panel mother substrate as an embodiment of the present invention.

FIG. 6 is an enlarged plan view for illustrating the main parts of the touch panel mother substrate illustrated in FIG. 5.

FIG. 7 is an enlarged cross-sectional view for illustrating the main parts in a VII-VII direction of FIG. 6.

### EMBODIMENTS OF THE INVENTION

A touch panel mother substrate according to an embodiment of the present invention is a touch panel mother substrate on which a plurality of touch panel units that become touch panels after being cut is formed, and includes an organic resin film deposited on a front side of the touch panel mother substrate and a cutting groove that opens on a surface of the organic resin film and extends in a predetermined direction, wherein materials of a bottom surface of the cutting groove and a back surface of the touch panel mother substrate have the same main ingredient (a first structure of the touch panel mother substrate).

In the first structure of the touch panel mother substrate, the bottom surface of the cutting groove is formed from a material having the same main ingredient as the back surface of the touch panel mother substrate. Thus, the bottom surface of the cutting groove actually has the same material as the back surface of the touch panel mother substrate. Accordingly, for example, a condition for use of the tool for cutting the touch panels does not need to be changed depending on the front side or the back side of the touch panel mother substrate. As a result of that, the cutting of touch panels from the touch panel mother substrate is facilitated.

A second structure of the touch panel mother substrate has a structure where an inorganic insulating film deposited on the front side of the touch panel mother substrate is further provided at a layer lower than the organic insulating film and the inorganic insulating film forms the bottom surface of the cutting groove in the first structure of the touch panel mother substrate. In such a structure, the bottom surface of the cutting groove actually has the same material as the back surface of the touch panel mother substrate. As a result of that, the cutting of touch panels from the touch panel mother substrate is facilitated.

A method for fabricating a touch panel according to an embodiment of the present invention is a method for fabricating a touch panel using a touch panel mother substrate on which a plurality of touch panel units that become touch panels after being cut is formed, and the method includes an organic resin film deposition process for depositing an organic resin film on a front side of the touch panel mother substrate, a cutting groove forming process for forming a cutting groove that opens on a surface of the organic resin film and extends in a predetermined direction, and a front side section line forming process for forming, at a bottom surface of the cutting groove, a front side section line for cutting the touch panel unit, and the bottom surface of the cutting groove is formed from a material having the same main ingredient as that of a back surface of the touch panel mother substrate (a first aspect of the method for fabricating a touch panel).

In the first aspect of the method for fabricating a touch panel, the bottom surface of the cutting groove is formed from a material having the same main ingredient as the back surface of the touch panel mother substrate. Thus, the bottom surface of the cutting groove actually has the same material as the back surface of the touch panel mother substrate. Accordingly, for example, a condition for use of the tool for cutting the touch panels does not need to be changed depending on the front side or the back side of the touch panel mother substrate. As a result of that, the cutting of touch panels from the touch panel mother substrate is facilitated.

As a second aspect of the method for fabricating a touch panel, the first aspect of the method for fabricating a touch panel further includes an inorganic insulating film deposition process for depositing an inorganic insulating film on the front side of the touch panel mother substrate before the organic resin film deposition process is performed, and performing the cutting groove forming process forms the bottom surface of the cutting groove with the inorganic insulating film. In such a structure, the bottom surface of the cutting groove actually has the same material as the back surface of the touch panel mother substrate. As a result of that, the cutting of touch panels from the touch panel mother substrate is facilitated.

As a third aspect of the method for fabricating a touch panel, the first or second aspect of the method for fabricating a touch panel further includes a back side section line forming process for forming, at the back surface of the touch panel mother substrate, a back side section line for cutting the touch panel unit. In such a structure, the cutting of touch panels from the touch panel mother substrate is facilitated.

A touch panel according to an embodiment of the present invention is a touch panel that has been cut from the touch panel mother substrate according to an embodiment of the present invention, or that has been fabricated by the method for fabricating a touch panel according to an embodiment of the present invention.

Hereinafter, a more detailed embodiment of the present invention will be described with reference to the drawings. Note that, for convenience of description, each of the drawings referred to below briefly illustrates only main parts necessary for describing the present invention among from the component parts of the embodiments of the present invention. Thus, the touch panel mother substrate and the touch panel according to the present invention can include a given component part that is not illustrated in each of the drawings referred to herein. Further, the dimensions of the parts in each of the drawings do not truly show the actual dimensions of the component parts, the dimensional ratio of each of the parts, and the like.

### Embodiment

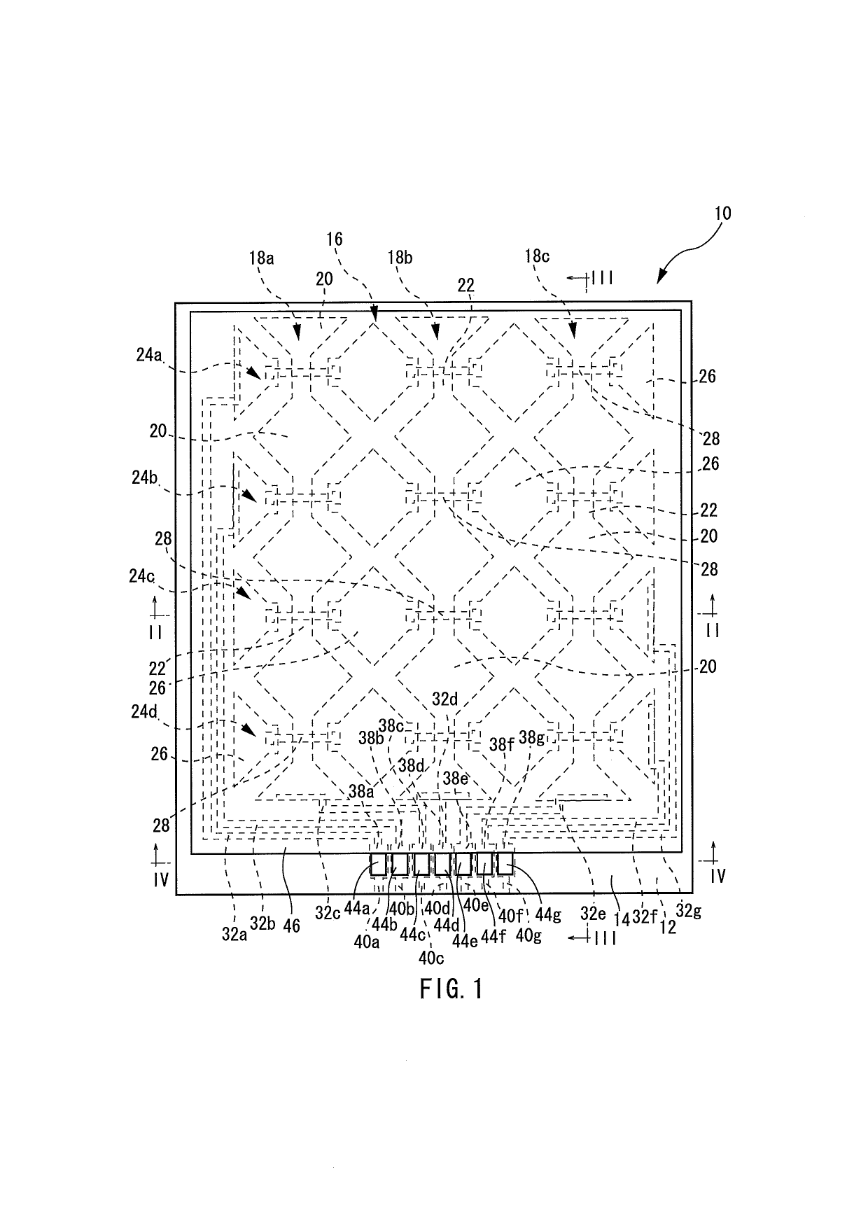

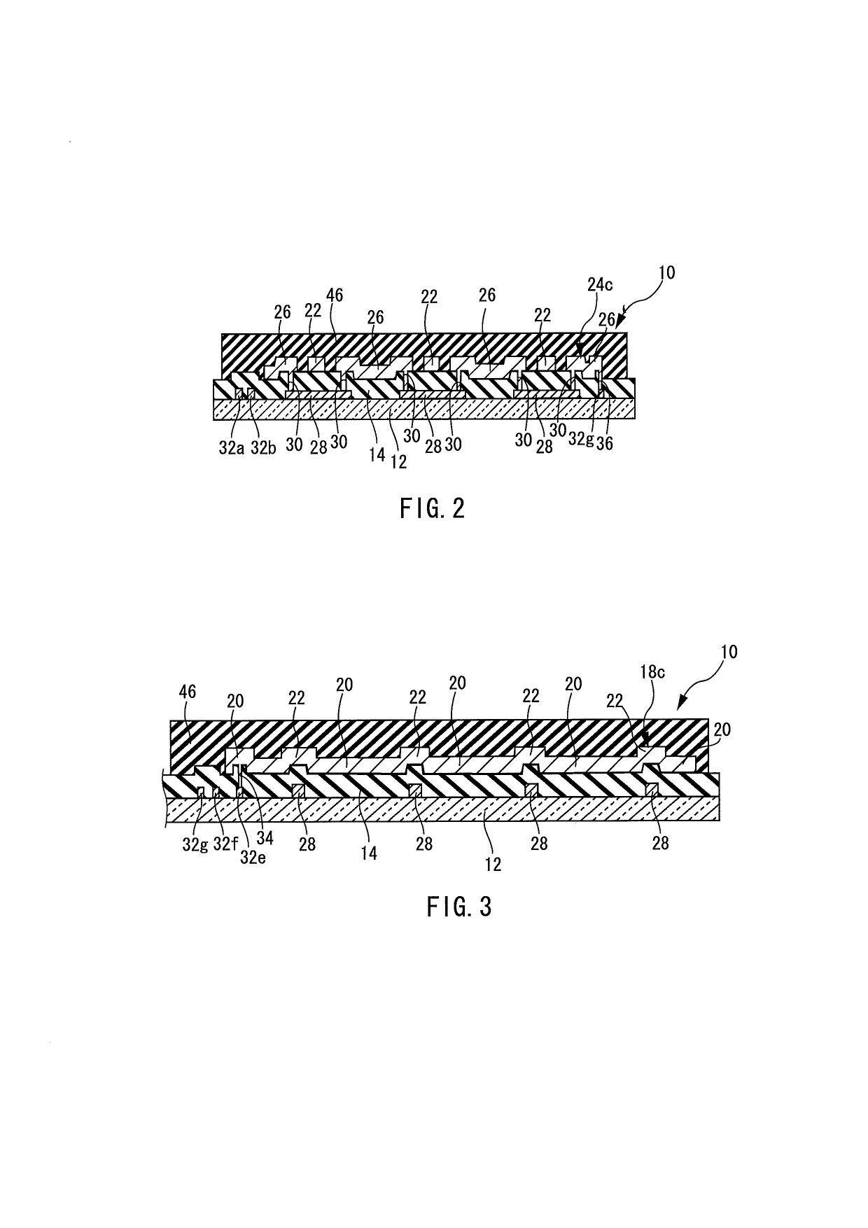

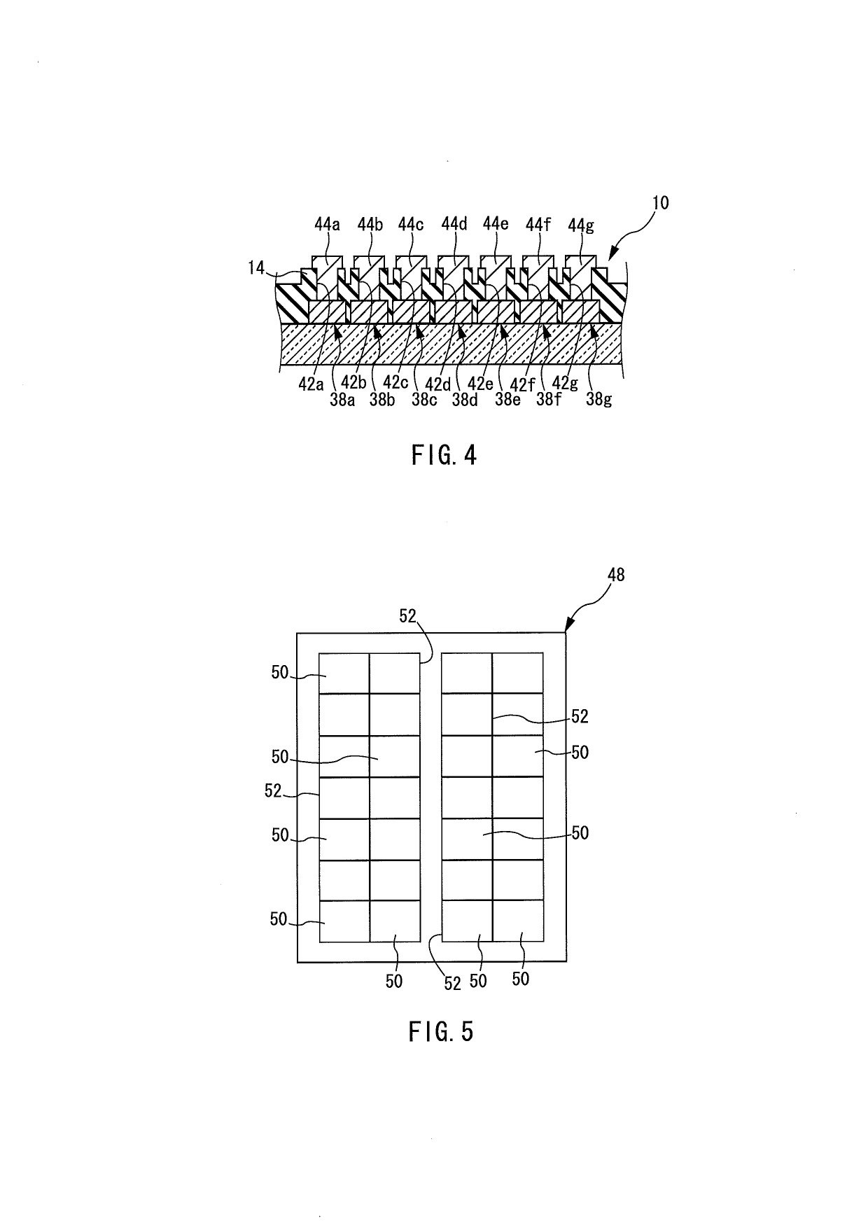

FIGS. 1 to 4 illustrate a touch panel 10 according to an embodiment of the present invention.

The touch panel 10 includes a substrate 12. For example, a substrate having silicon as the main ingredient, such as a glass substrate, can be adopted as the substrate 12.

An insulating film 14 is formed on the substrate 12. For example, an inorganic insulating film having silicon as the main ingredient, such as a silicon oxide film or a silicon nitride film, can be adopted as the insulating film 14.

A touch electrode 16 working as a touched position detecting element is formed on the upper surface side of the substrate 12. An area in which the touch electrode 16 is formed is an input area for the touch panel 10.

The touch electrode 16 includes a plurality of longitudinal electrodes 18a to 18c and a plurality of lateral electrodes 24a to 24d. Note that, to facilitate understanding, an arbitrary number of the longitudinal electrodes 18a to 18c and an arbitrary number of the lateral electrodes 24a to 24d are illustrated in the drawing. However, the number of the electrodes is on a voluntary basis.

For example, an indium tin oxide (ITO) film or the like can be adopted as the longitudinal electrodes 18a to 18c. The longitudinal electrodes 18a to 18c include a plurality of island shaped electrode portions 20, and a plurality of bridge wiring portions 22. Note that, to facilitate understanding, an arbitrary number of the island shaped electrode portions 20 and an arbitrary number of the bridge wiring portions 22 are illustrated in the drawing. However, the number of the island shaped electrode portions and the number of the bridge wiring portions are on a voluntary basis.

The island shaped electrode portions 20 and the bridge wiring portions 22 are formed on the insulating film 14 in such a way as to alternately align, so that the longitudinal electrodes 18a to 18c extend along a side of the substrate 12 (a side extending in a vertical direction of FIG. 1).

The lateral electrodes 24a to 24d include a plurality of island shaped electrode portions 26, and a plurality of bridge wiring portions 28. Note that, to facilitate understanding, an arbitrary number of the island shaped electrode portions 26 and an arbitrary number of the bridge wiring portions 28 are illustrated in the drawing. However, the number of the island shaped electrode portions and the number of the bridge wiring portions are on a voluntary basis.

The island shaped electrode portions 26 are formed on the insulating film 14. For example, an indium tin oxide (ITO) film or the like can be adopted as the island shaped electrode portions 26.

The bridge wiring portions 28 are formed on the substrate 12 and are covered by the insulating film 14. For example, a laminated metal film including a titanium film, an aluminum film, and a titanium nitride film that are laminated in this order can be adopted as the bridge wiring portions 28.

The island shaped electrode portions 26 and the bridge wiring portions 28 are formed in such a way as to alternately align in the planar view of the substrate 12, so that the lateral electrodes 24a to 24d extend along a side of the substrate 12 (a side extending in a horizontal direction of FIG. 1). Note that the island shaped electrode portions 26 are electrically connected to the bridge wiring portions 28 through contact holes 30 that are formed while penetrating through the insulating film 14 in a thickness direction.

A plurality of internal wirings 32a to 32g working as wirings is formed on the substrate 12. Note that, to facilitate understanding, an arbitrary number of the internal wirings 32a to 32g is illustrated in the drawing. However, the number of the internal wirings is on a voluntary basis.

For example, a laminated metal film including a titanium film, an aluminum film, and a titanium nitride film that are laminated in this order can be adopted as the internal wirings 32a to 32g.

The internal wirings 32c to 32e are connected to the longitudinal electrodes 18a to 18c, respectively, from among the internal wirings 32a to 32g. The other internal wirings 32a, 32b, 32f, and 32g are connected to the lateral electrodes 28a to 28d, respectively. In other words, the internal wirings are connected to the longitudinal electrodes and the lateral electrodes one by one. Note that the internal wirings 32c to 32e are electrically connected to the longitudinal electrodes 18a to 18c and the internal wirings 32a, 32b, 32f, and 32g are electrically connected to the lateral electrodes 24a to 24d through contact holes 34 and 36, respectively. The contact holes 34 and 36 are formed while penetrating through the insulating film 14 in a thickness direction.

Terminal portions 38a to 38g are formed at the protruding ends of the internal wirings 32a to 32g. For example, a laminated metal film including a titanium film, an aluminum film, and a titanium nitride film that are laminated in this order can be adopted as the terminal portions 38a to 38g. Each of the terminal portions 38a to 38g has a larger line width than that of each of the internal wirings 32a to 32g and is formed in such a way as to extend in a direction in which the internal wirings 32a to 32g protrude, having a rectangular shape in the planar view of the substrate 12.

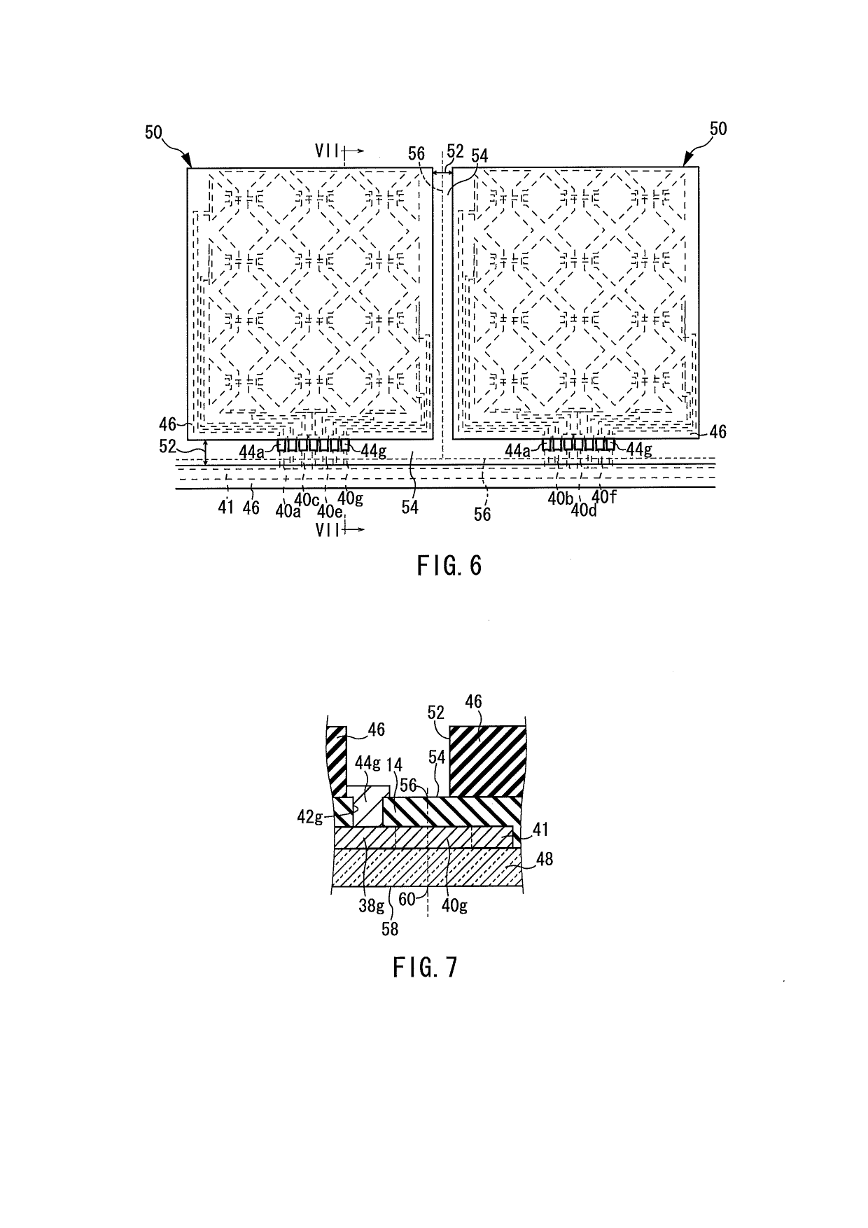

The external wirings 40a to 40g extending to the opposite side of the internal wirings 32a to 32g are connected to the terminal portions 38a to 38g. The external wirings 40a to 40g extend even to the outer edge of the substrate 12. Note that a short ring 41 (see FIG. 6 and FIG. 7) is connected to a side of the external wirings 40a to 40g that is opposite to the terminal portions 38a to 38g. The short ring 41 is for discharging static electricity before the touch panel 10 is cut from a touch panel mother substrate 48 described below.

The upper surfaces of the terminal portions 38a to 38g are covered with the insulating film 14. Especially, the side surfaces of the terminal portions 38a to 38g are also covered with the insulating film 14 in the present embodiment.

Openings 42a to 42g are formed at the position corresponding to the terminal portions 38a to 38g in the insulating film 14, penetrating through the insulating film 14 in a thickness direction. Thus, a part of the upper surface of each of the terminal portions 38a to 38g is not covered with the insulating film 14.

Each of the openings 42a to 42g has a smaller rectangular shape than each of the terminal portions 38a to 38g in the planar view of the substrate 12. The openings 42a to 42g are formed at a position where the whole of them are overlapped with the terminal portions 38a to 38g in the planar view of the substrate 12.

Transparent conductive films 44a to 44g are formed at the position corresponding to the terminal portions 38a to 38g on the insulating film 14. For example, an indium tin oxide (ITO) film or the like can be adopted as the transparent conductive films 44a to 44g.

The transparent conductive films 44a to 44g fill in the openings 42a to 42g. Thus, a part of the upper surface of each of the terminal portions 38a to 38g is covered with each of the transparent conductive films 44a to 44g. The other parts of each of the terminal portions 38a to 38g are covered with the insulating film 14.

A protective film 46 that is an organic resin film is formed on the upper surface side of the substrate 12. For example, an acrylic resin film or the like can be adopted as the protective film 46. The protective film 46 covers the longitudinal electrodes 22a to 22c and the island shaped electrode portions 26 of the lateral electrode 28a to 28d. The protective film 46 does not cover the transparent conductive films 44a to 44g. The transparent conductive films 44a to 44g are externally exposed.

The touch panel 10 is used, for example, as attached to a display panel such as a liquid crystal panel. While the touch panel 10 is attached to the display panel, the input area of the touch panel 10 overlaps with the display area of the display panel.

A flexible printed board (not shown in the drawings) that is an external circuit is connected to the touch panel 10. Concretely, a connecting terminal included in the flexible printed board is connected the transparent conductive films 44a to 44g through an anisotropic conductive film (ACF) (not shown in the drawings). This electrically connects the flexible printed board to the terminal portions 38a to 38g through the transparent conductive films 44a to 44g and the anisotropic conductive film (not shown in the drawings).

As for the touch panel 10, a touched position is detected by capturing the variation of the capacitance that is generated between the observer's finger, and one of the longitudinal electrodes 22a to 22c and one of the lateral electrode 28a to 28d that are positioned near the finger when the finger touches a cover glass substrate (not shown in the drawings) that is positioned in such a way as to cover the protective film 46. In other words, the touch panel 10 of the present embodiment is a so-called projected capacitive type touch panel.

Next, a method for fabricating the touch panel 10 will be described. Note that methods for fabricating the touch panel 10 are not limited to the method described below.

FIG. 5 illustrates the touch panel mother substrate 48. A plurality of touch panel units 50 is formed on the touch panel mother substrate 48. Each of touch panel units 50 becomes the touch panel 10 after being cut from the touch panel mother substrate 48. In other words, the touch panel 10 is fabricated by cutting, from a large touch panel mother substrate 48, the plurality of touch panel units 50 that have been gathered and formed on the touch panel mother substrate 48.

First, the bridge wiring portions 28 of the lateral electrodes 24a to 24d, the internal wirings 32a to 32g, the terminal portions 38a to 38g, and the external wirings 40a to 40g are formed on each of the touch panel units 50 and the short ring 41 (see FIGS. 6 and 7) is formed over the whole of the touch panel mother substrate 48. Concretely, metal films that are to be the bridge wiring portions 28, the internal wirings 32a to 32g, the terminal portions 38a to 38g, the external wirings 40a to 40g, and the short ring 41 later are formed on the whole upper surface of the touch panel mother substrate 48 by sputtering. After that, the metal films are patterned by photolithography. This forms the bridge wiring portions 28 of the lateral electrodes 24a to 24d, the internal wirings 32a to 32g, the terminal portions 38a to 38g, and the external wirings 40a to 40g on each of the touch panel units 50 and forms the short ring 41 over the whole of the touch panel mother substrate 48.

Next, an inorganic insulating film deposition process for forming the insulating film 14 on the upper surface side of the touch panel mother substrate 48 by Chemical Vapor Deposition (CVD) is performed. The whole upper surface of the touch panel mother substrate 48 is covered with the insulating film 14 by the process. As a result of that, the bridge wiring portions 28 of the lateral electrodes 24a to 24d, the internal wirings 36a to 36g, the terminal portions 38a to 38g, the external wirings 40a to 40g, and the short ring 41 are covered with the insulating film 14.

The contact holes 30, 34, and 36 and the openings 42a to 42g penetrating through the insulating film 14 in a thickness direction are formed at the insulating film 14 that has formed in the above-described manner in each of the touch panel units 50. The contact holes 30, 34, and 36 and the openings 42a to 42g are formed by photolithography.

Next, the longitudinal electrodes 18a to 18c, the island shaped electrode portions 26 of the lateral electrodes 24a to 24d, and the transparent conductive films 44a to 44g are formed at each of the touch panel units 50. Concretely, ITO films that are to be the longitudinal electrodes 18a to 18c, the island shaped electrode portions 26 of the lateral electrodes 24a to 24d, and the transparent conductive films 44a to 44g later are formed on the whole upper surface of the touch panel mother substrate 48 by sputtering. After that, the ITO films are patterned by photolithography. This forms the longitudinal electrodes 18a to 18c, the island shaped electrode portions 26 of the lateral electrodes 24a to 24d, and the transparent conductive films 44a to 44g at each of the touch panel units 50.

Next, an organic resin film deposition process for forming the protective film 46 at each of the touch panel units 50 is performed. Concretely, the protective film 46 is formed, for example, by a spin coating application method, a spray application method, or the like.

As enlarged and illustrated in FIGS. 6 and 7, a cutting groove 52 is formed on the touch panel mother substrate 48 on which the protective film 46 is formed at each of the touch panel units 50.

The cutting groove 52 opens at the front side of the protective film 46 and extends parallel to each of the sides of the touch panel 10 (the touch panel units 50). The cutting groove 52 can be provided at least at the position at which a front side section line 56 described below is formed.

The cutting groove 52 can be formed, for example, using a metal mask stencil or the like for forming the protective film 46. In the present embodiment, a cutting groove forming process for forming the cutting groove 52 and the organic resin film deposition process are simultaneously performed.

The protective film 46 is not provided at the position at which the cutting groove 52 is formed, so that the insulating film 14 is exposed. In other words, the upper surface of the insulating film 14 is a bottom surface 54 of the cutting groove 52.

Further, the transparent conductive films 44a to 44g are not covered with the protective film 46 and are externally exposed. In other words, the transparent conductive films 44a to 44g are positioned at the bottom of the cutting groove 52. The cutting groove 52 including the transparent conductive films 44a to 44g at the bottom is formed nearer the transparent conductive films 44a to 44g than the short ring 41.

The touch panel 10 is cut from the touch panel mother substrate 48 at which the cutting groove 52 has been formed as described above.

Concretely, a front side section line forming process for forming the front side section line 56 at the bottom surface of the cutting groove 52 is performed on the front side of the touch panel mother substrate 48 using a wheel-shaped cutter. In the cutting groove 52 including the transparent conductive films 44a to 44g at the bottom, the front side section line 56 is formed at the bottom surface 54 of the cutting groove 52 in such a way to cross the external wirings 40a to 40g (see FIG. 7).

On a back surface 58 of the touch panel mother substrate 48, a back side section line forming process for forming a back side section line 60 is performed using a wheel-shaped cutter at the position corresponding to the front side section line 56 that has been formed at the front side (the front side section line 56 that has been formed at the bottom surface 54 of the cutting groove 52).

Then, as the section lines 56 and 60 have been formed on both of the front and back side of the touch panel mother substrate 48, applying a proper pressure on the touch panel mother substrate 48 cuts each of the touch panel units 50 from the touch panel mother substrate 48. This gives a desired touch panel 10.

Using the above-mentioned touch panel mother substrate 48 can easily cut the touch panel 10.

To describe in detail, the touch panel mother substrate 48 is formed from a glass substrate (that is composed mainly of silicon). On the other hand, the insulating film 14 is formed from an inorganic insulating film that is composed mainly of silicon such as a silicon oxide film, a silicon nitride film or the like. In other words, each of the insulating film 14 that form the bottom surface 54 of the cutting groove 52 and the touch panel mother substrate 48 is formed from an inorganic material that is composed mainly of silicon. This means that the bottom surface 54 of the cutting groove 52 on which the front side section line 56 is formed at the front side of the touch panel mother substrate 48 actually has the same material as the back surface of the touch panel mother substrate 48 on which the back side section line 60 is formed. Accordingly, for example, a condition for use of the wheel-shaped cutter for forming the section lines 56 an 60 on the front side and back side of the touch panel mother substrate 48 does not need to be changed depending on the front side or the back side of the touch panel mother substrate 48. As a result of that, the operation for cutting the touch panel 10 from the touch panel mother substrate 48 is facilitated. In other words, the protective film 46 is thoroughly removed from the position at which the front side section line 56 is formed on the touch panel mother substrate 48. This nearly equalizes the conditions for cutting the front side and the back side of the touch panel mother substrate 48 so that the touch panel mother substrate 48 can easily be cut. Further, this can also prevent a crack caused by cutting the touch panel 10 from the touch panel mother substrate 48.

The embodiment of the present invention has been described above in detail. However, the embodiment is only an example and the present invention is not limited to the above-mentioned embodiment at all.

For example, the front surface of the touch panel mother substrate 48 can form the bottom surface of the cutting groove in the above-mentioned embodiment.

A concrete example in which the present invention is applied to a projected capacitive type touch panel has been described in the above-mentioned embodiment. However, the touch panel to which the present invention can be applied is not limited to the projected capacitive type touch panel. The present invention is applicable to various types of touch panels, for example, a surface capacitive type touch panel, a resistive touch panel, an infrared touch panel, an ultrasonic touch panel, an electromagnetic induction type touch panel, and the like.

1. A touch panel mother substrate on which a plurality of touch panel units that become touch panels after being cut is formed, the touch panel mother substrate comprising:
an organic resin film deposited on a front side of the touch panel mother substrate; and
a cutting groove that opens on a surface of the organic resin film and extends in a predetermined direction,
wherein materials of a bottom surface of the cutting groove and a back surface of the touch panel mother substrate have the same main ingredient.

2. The touch panel mother substrate according to claim 1, further comprising:
an inorganic insulating film provided at a layer lower than the organic resin film, the inorganic insulating film being deposited on the front side of the touch panel mother substrate,
wherein the inorganic insulating film forms the bottom surface of the cutting groove.

3. A method for fabricating a touch panel using a touch panel mother substrate on which a plurality of touch panel units that become touch panels after being cut is formed, the method comprising:
an organic resin film deposition process for depositing an organic resin film on a front side of the touch panel mother substrate;
a cutting groove forming process for forming a cutting groove that opens on a surface of the organic resin film and extends in a predetermined direction;
a front side section line forming process for forming, at a bottom surface of the cutting groove, a front side section line for cutting the touch panel unit,
wherein the bottom surface of the cutting groove is formed from a material having the same main ingredient as that of a back surface of the touch panel mother substrate.

4. The method for fabricating a touch panel according claim 3, further comprising:
an inorganic insulating film deposition process for depositing an inorganic insulating film on the front side of the touch panel mother substrate before the organic resin film deposition process is performed,
wherein performing the cutting groove forming process forms the bottom surface of the cutting groove with the inorganic insulating film.

5. The method for fabricating a touch panel according claim 3, further comprising:
a back side section line forming process for forming, at the back surface of the touch panel mother substrate, a back side section line for cutting the touch panel unit.

6. A touch panel cut from the touch panel mother substrate according to claim 1.

7. A touch panel fabricated by the method for fabricating a touch panel according to claim 3.
